(19) United States
(12) Patent Application Publication
(10) Pub. No.: US 2025/0202219 A1
(43) Pub. Date: Jun. 19, 2025

(54) ELECTRONIC CONTROL APPARATUS AND BRAKE APPARATUS

(71) Applicant: HL MANDO CORPORATION, Pyeongtaek-si (KR)

(72) Inventor: Gonjae LEE, Pyeongtaek-si (KR)

(21) Appl. No.: 18/898,340

(22) Filed: Sep. 26, 2024

(30) Foreign Application Priority Data
Dec. 18, 2023 (KR) 10-2023-0184572

(51) Int. Cl. H02H 1/00; H02H 3/04

(52) U.S. Cl. CPC H02H 1/0023; H02H 3/04

(57) ABSTRACT

An electronic control apparatus may include a printed circuit board on which electrical circuits are mounted, a power connector provided on the printed circuit board and electrically connected to an external power source, a power circuit configured to receive external power through the power connector and supply power to the electrical circuits, an ultraviolet sensor mounted on the printed circuit board, and configured to detect ultraviolet light and output an ultraviolet detected signal corresponding to the detection of the ultraviolet light, and a processor configured to block power supply to at least one part of the electrical circuits in response to the ultraviolet detected signal from the ultraviolet sensor.

### CROSS-REFERENCE TO RELATED APPLICATION(S)

This application is based on and claims priority under 35 U.S.C. § 119 to Korean Patent Application No. 10-2023-0184572, filed on Dec. 18, 2023, in the Korean Intellectual Property Office, the disclosure of which is incorporated by reference herein in its entirety.

### BACKGROUND

### Technical Field

The disclosure relates to an electronic control apparatus and a brake apparatus capable of detecting an ark or spark.

### Description of the Related Art

Recently, various electrical/electronic apparatuses are installed in vehicles. For example, the number of electrical/electronic apparatuses in vehicles, such as Engine Control Unit (ECU) that controls the engine or motor, Transmission Control Unit (TCU) that controls the transmission, Electronic Brake Control Module (EBCM) that controls the brake, and Electric Power Steering (EPS), is increasing gradually.

According to an increase of electrical/electronic apparatuses in vehicles, fire accidents in vehicles caused by ignition of the electrical/electronic apparatuses are also increasing. A fire in a vehicle may lead to an explosion of fuel stored in the fuel tank or an explosion of the battery, which may endanger not only the driver of the vehicle but also other people around the vehicle.

Ignition of electrical/electronic apparatuses in a vehicle occurs for a variety of causes. One of the causes of such ignition is an arc or spark occurred in the internal circuit of the electrical/electronic apparatuses, and the arc or spark may spread to flammable substances included in the electrical/electronic apparatuses to result in a fire.

### BRIEF SUMMARY

It is an aspect of the disclosure to provide an electronic control apparatus and a brake apparatus capable of detecting an arc or spark as a starting point of a fire that occurs in an electrical/electronic apparatus.

Additional aspects of the disclosure will be set forth in part in the description which follows and, in part, will be obvious from the description, or may be learned by practice of the disclosure.

In accordance with an aspect of the disclosure, an electronic control apparatus may include a printed circuit board on which electrical circuits are mounted, a power connector provided on the printed circuit board and electrically connected to an external power source, a power circuit configured to receive external power through the power connector and supply power to the electrical circuits, an ultraviolet sensor mounted on the printed circuit board, and configured to detect ultraviolet light and output an ultraviolet detected signal corresponding to the detection of the ultraviolet light, and a processor configured to block power supply to at least one part of the electrical circuits in response to the ultraviolet detected signal from the ultraviolet sensor.

The ultraviolet sensor may include a photodiode configured to output the ultraviolet detected signal corresponding to detection of Ultraviolet-C (UV-C) having a wavelength range of 100 nm to 280 nm.

The ultraviolet sensor may include a sensor substrate supporting the photodiode, a side wall surrounding the photodiode, and an opening through which the UV-C passes.

The ultraviolet sensor may be provided on the printed circuit board such that the opening faces the power connector.

The ultraviolet sensor may be provided on the printed circuit board such that the photodiode faces the power connector.

The ultraviolet sensor may be provided around the power connector.

A distance between the ultraviolet sensor and the power connector may be less than half a maximum width of the printed circuit board.

The ultraviolet sensor may be provided at a corner region or an edge region of the printed circuit board.

The electronic control apparatus may further include an actuator connector provided on the printed circuit board and electrically connected to an actuator, a driving circuit configured to receive power from the power circuit and control power that is to be supplied to the actuator, and another ultraviolet sensor provided on the printed circuit board, and configured to detect ultraviolet light and output another ultraviolet detected signal corresponding to the detection of the ultraviolet light. The processor may block power supply to the driving circuit in response to the other ultraviolet detected signal from the other ultraviolet sensor.

The other ultraviolet sensor may include another photodiode configured to output the other ultraviolet detected signal corresponding to detection of UV-C having a wavelength range of 100 nm to 280 nm.

The other ultraviolet sensor may be provided on the printed circuit board such that the other photodiode faces the actuator connector.

The other ultraviolet sensor may be provided around the actuator connector.

A distance between the other ultraviolet sensor and the power connector may be less than half a maximum width of the printed circuit board.

The processor may provide a warning message to a driver through a display or a speaker of a vehicle, in response to the ultraviolet detected signal from the ultraviolet sensor.

In accordance with an aspect of the disclosure, an electronic control apparatus may include a first printed circuit board on which electrical circuits are mounted, a power connector provided on the first printed circuit board and electrically connected to an external power source, a power circuit configured to receive external power from the power connector and supply power to the electrical circuits, an ultraviolet sensor module including a second printed circuit board electrically connected to the first printed circuit board, and an ultraviolet sensor provided on the second printed circuit board and configured to output an ultraviolet detected signal corresponding to detection of ultraviolet light, and a processor configured to block power supply to at least one part of the electrical circuits in response to the ultraviolet detected signal from the ultraviolet sensor module.

The second printed circuit board may be provided parallel to the first printed circuit board, and the ultraviolet sensor may be provided on a first surface of the second printed circuit board, the first surface facing the first printed circuit board.

The electronic control apparatus may further include an actuator connector provided on the first printed circuit board and electrically connected to an actuator, and a driving circuit configured to receive power from the power circuit and control power that is to be supplied to the actuator. The ultraviolet sensor module may further include another ultraviolet sensor provided on the second printed circuit board and configured to output another ultraviolet detected signal corresponding to detection of ultraviolet light. The processor may block power supply to the driving circuit in response to the other ultraviolet detected signal from the other ultraviolet sensor.

The second printed circuit board may be provided vertical to the first printed circuit board. The ultraviolet sensor may be provided on a first surface of the second printed circuit board, facing the power connector. The other ultraviolet sensor may be provided on a second surface of the second printed circuit board, the first surface facing the actuator connector.

The processor may provide a warning message to a driver through a display or a speaker of a vehicle, in response to the ultraviolet detected signal from the ultraviolet sensor.

In accordance with an aspect of the disclosure, a brake apparatus may include a valve, a motor, and an electronic control apparatus configured to drive at least one of the valve and the motor. The electronic control apparatus may include a printed circuit board, a power connector provided on the printed circuit board and electrically connected to an external power source, a power circuit configured to receive external power through the power connector and supply power to electrical circuits, a first ultraviolet sensor provided around the power connector, and configured to detect ultraviolet light and output a first ultraviolet detected signal corresponding to the detection of the ultraviolet light, an actuator connector provided on the printed circuit board and electrically connected to at least one of the valve and the motor, a driving circuit configured to receive power from the power circuit and control power that is to be supplied to at least one of the valve and the motor, a second ultraviolet sensor provided around the actuator connector, and configured to detect ultraviolet light and output a second ultraviolet detected signal corresponding to the detection of the ultraviolet light, and a processor configured to limit an operation of at least one of the electrical circuits and the driving circuit, in response to the first ultraviolet detected signal and the second ultraviolet detected signal.

### BRIEF DESCRIPTION OF THE SEVERAL VIEWS OF THE DRAWINGS

These and/or other aspects of the disclosure will become apparent and more readily appreciated from the following description of the embodiments, taken in conjunction with the accompanying drawings of which:

FIG. 1 shows a brake apparatus including an electronic control apparatus according to an embodiment;

FIG. 2 shows an example of an output signal from an ultraviolet sensor included in an electronic control apparatus according to an embodiment;

FIG. 3 shows an outer appearance of an electronic control apparatus and a valve according to an embodiment;

FIG. 4 is an exploded perspective view of an electronic control apparatus and a valve according to an embodiment, shown in one direction;

FIG. 5 is an exploded perspective view of an electronic control apparatus and a valve according to an embodiment, shown in another direction;

FIG. 6 shows an example of an ultraviolet sensor included in an electronic control apparatus according to an embodiment;

FIGS. 7A, 7B, and 7C show structures of ultraviolet sensors included in an electronic control apparatus according to an embodiment;

FIGS. 8A, 8B, and 8C show structures of ultraviolet sensors included in an electronic control apparatus according to an embodiment;

FIGS. 9A, 9B, and 9C show structures of ultraviolet sensors included in an electronic control apparatus according to an embodiment;

FIGS. 10A, 10B, and 10C show structures of ultraviolet sensors included in an electronic control apparatus according to an embodiment;

FIGS. 11A and 11B show structures of ultraviolet sensors included in an electronic control apparatus according to an embodiment;

FIGS. 12A and 12B show structures of ultraviolet sensors included in an electronic control apparatus according to an embodiment;

FIG. 13 shows a first surface of a first printed circuit board included in an electronic control apparatus according to an embodiment;

FIG. 14 shows a second surface of a first printed circuit board included in an electronic control apparatus according to an embodiment;

FIG. 15 shows a first surface of a first printed circuit board included in an electronic control apparatus according to an embodiment;

FIG. 16 shows a second surface of a first printed circuit board included in an electronic control apparatus according to an embodiment;

FIG. 17 shows an example of a circuit configuration of an ultraviolet sensor module included in an electronic control apparatus according to an embodiment;

FIG. 18 shows an example of a first printed circuit board and an ultraviolet sensor module included in an electronic control apparatus according to an embodiment; and

FIG. 19 shows an example of a first printed circuit board and an ultraviolet sensor module included in an electronic control apparatus according to an embodiment.

### DETAILED DESCRIPTION

Like reference numerals refer to like components throughout the specification. This specification does not describe all the components of the embodiments, and duplicative contents between embodiments or general contents in the technical field of the disclosure will be omitted. The terms ‘portion,’ ‘module,’ ‘member,’ and ‘block’ used in this specification may be embodied as software or hardware, and it is also possible for a plurality of ‘portions,’ ‘modules,’ ‘members,’ and ‘blocks’ to be embodied as one component, or one ‘portion,’ ‘module,’ ‘member,’ and ‘block’ to include a plurality of components according to embodiments.

Throughout the specification, when a portion is referred to as being “connected” to another portion, it includes not only a direct connection but also an indirect connection, and the indirect connection includes connecting through a wireless network.

Also, when it is described that a portion “includes” a component, it means that the portion may further include other components, not excluding the other components unless specifically stated otherwise.

Throughout the specification, when a member is described as being “on” another member, this includes not only a case in which a member is in contact with another member but also a case in which another member is present between the two members.

The terms ‘first,’ ‘second,’ etc. are used to distinguish one component from another component, and the components are not limited by the above-mentioned terms.

The singular forms “a,” “an,” and “the” include plural referents unless the context clearly dictates otherwise.

In each step, an identification numeral is used for convenience of explanation, the identification numeral does not describe the order of the steps, and each step may be performed differently from the order specified unless the context clearly states a particular order.

Hereinafter, the operation principle and embodiments of the disclosure will be described with reference to the accompanying drawings.

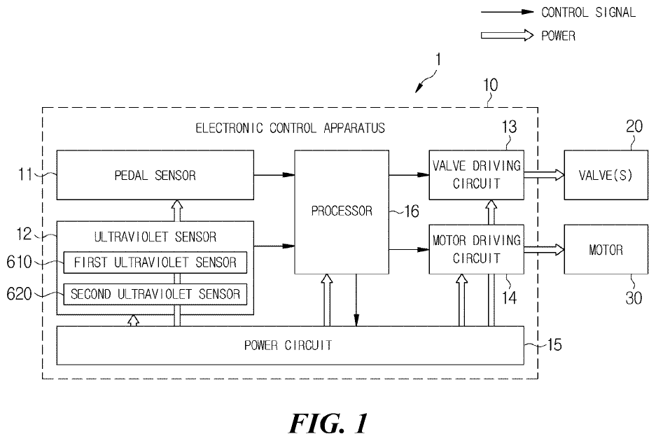

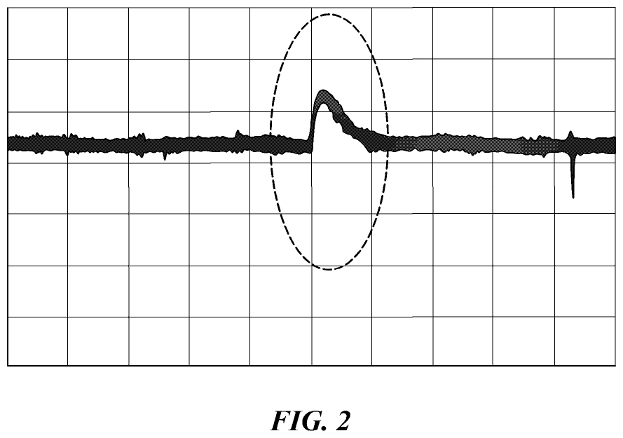

FIG. 1 shows a brake apparatus including an electronic control apparatus according to an embodiment, and FIG. 2 shows an example of an output signal from an ultraviolet sensor included in an electronic control apparatus according to an embodiment.

An electronic control apparatus 10 installed in a brake apparatus 1 shown in FIG. 1 may be an example of an electronic control apparatus according to the disclosure. The electronic control apparatus according to the disclosure may correspond to any one of electrical/electronic apparatuses installed in a vehicle. The electronic control apparatus 10 according to the disclosure may be, for example, an Engine Control Unit (ECU), a Transmission Control Unit (TCU), an Electronic Control Unit (ECU) of an Electric Power Steering (EPS), a Body Control Unit (BCU), or a Vehicle Control Unit (VCU).

As shown in FIG. 1, the brake apparatus 1 may include the electronic control apparatus 10, a valve 20, and/or a motor 30. The valve 20 and the motor 30 shown in FIG. 1 may not be essential components of the disclosure, and the valve 20 and the motor 30 may be omitted.

The brake apparatus 1 may provide pressure (hereinafter, referred to as ‘hydraulic pressure’) of a pressing medium (for example, brake oil, etc.) for braking the vehicle to a plurality of wheels installed in the vehicle.

For example, the brake apparatus 1 may include a hydraulic pressure supply for generating hydraulic pressure and a hydraulic pressure controller for controlling generated hydraulic pressure. The hydraulic pressure supply may include, for example, a piston-cylinder pump or a rotary pump, which is driven by the motor 30. The hydraulic pressure controller may include, for example, flow paths extending from the hydraulic pressure supply to wheel cylinders installed in the wheels of the vehicle, and a plurality of valves for opening or closing the flow paths.

The motor 30 may provide power (torque) for generating hydraulic pressure to the piston-cylinder pump or the rotary pump. For example, the torque of the motor 30 may be converted into a translational force by a power conversion device (for example, spindle-nut, pinon-rack, etc.), and a piston of the piston-cylinder pump may perform a translational motion by the translational force. Also, a rotor of the rotary pump may rotate by the torque of the motor 30.

The motor 30 may include, for example, a rotor and a stator, and the rotor or the stator may include a plurality of coils that generate a rotating magnetic field. The motor 30 may be driven by motor driving current that is supplied to the plurality of coils.

The valve 20 may allow or block hydraulic pressure that is generated by the hydraulic pressure supply and provided to the wheel cylinders. In addition, the valve 20 may modulate or regulate hydraulic pressure that is generated by the hydraulic pressure supply and provided to the wheel cylinders.

The valve 20 may include, for example, a solenoid valve that is electrically controllable. The solenoid valve may include a coil that generates a magnetic field. The valve 20 may be opened (normal close type valve) or closed (normal open type valve) by valve driving current that is supplied to the coil.

The electronic control apparatus 10 may control the motor 30 and/or the valve 20 in response to a driver's control or a control by an upper control device.

For example, as shown in FIG. 1, the electronic control apparatus 10 may include a pedal sensor 11, an ultraviolet sensor 12, a valve driving circuit 13, a motor driving circuit 14, a power circuit 15, and/or a processor 16. The pedal sensor 11, the valve driving circuit 13, and the motor driving circuit 14 shown in FIG. 1 may not be essential components of the electronic control apparatus 10 according to an embodiment, and the pedal sensor 11, the valve driving circuit 13, and the motor driving circuit 14 may be omitted.

The pedal sensor 11 may detect a movement of a brake pedal as a driver's braking intention, and output an electrical signal (hereinafter, referred to as a ‘pedal signal’) corresponding to the movement of the brake pedal. The brake pedal may move by the driver, and the pedal sensor 11 may detect a movement of the brake pedal by the driver. The pedal sensor 11 may output a pedal signal corresponding to displacement of the brake pedal or moving speed of the brake pedal, to the processor 16.

The ultraviolet sensor 12 may be provided inside the electronic control apparatus 10 that blocks external light, and detect ultraviolet light generated in the electronic control apparatus 10. For example, the ultraviolet sensor 12 may detect Ultraviolet-C (UV-C) generated in the electronic control apparatus 10.

Due to a failure of an electronic circuit, a failure of a power supply, etc., a spark or arc may occur inside the electronic control apparatus 10. For example, when sudden current flows into the power circuit 15 or a sudden voltage is applied to the power circuit 15, insulation between a power terminal (or power line) and a ground terminal (or ground line) of the power circuit 15 may break down, which may cause a spark between the power terminal and the ground terminal. Also, when current supplied to the motor 30 or the valve 20 is suddenly cut off, insulation between terminals of the motor 30 or the valve 20 may break down due to an induced electromotive force of the coil included in the motor 30 or the valve 20, which may cause repetitive arcs between the terminals of the motor 30 or the valve 20.

A spark or arc occurred inside the electronic control apparatus 10 may lead to a fire in the electronic control apparatus 10. For example, many flammable components exist inside the electronic control apparatus 10, and a spark or arc may cause a fire in the flammable components.

A fire occurred in the electronic control apparatus 10 may spread to the entire vehicle. For example, when power is continuously supplied to the electronic control apparatus 10 ignited by a spark or arc, sparks or arcs may occur repetitively and thus, a fire in the electronic control apparatus 10 may spread. Furthermore, the fire in the electronic control apparatus 10 may spread to the entire vehicle along power lines or communication lines inside the vehicle.

As such, a spark or arc occurred inside the electronic control apparatus 10 may cause a fire in the electronic control apparatus 10 and even a fire in the vehicle.

The spark or arc may include emission of ultraviolet light, particularly, UV-C. UV-C may be light having a wavelength range of about 100 nm to about 280 nm. Because UV-C is absorbed by the ozone layer, UV-C is generally undetectable. Accordingly, detecting UV-C lowers a possibility of wrongly detecting a spark or arc.

The ultraviolet sensor 12 may include a photodiode for detecting ultraviolet light, particularly, UV-C. The photodiode may be made of a semiconductor material capable of absorbing, for example, UV-C. For example, the photodiode may include a PN junction diode made of gallium oxide (Ga₂O₃), gallium nitride (GaN), silicon carbide (SiC), or diamond (C). An energy band gap of gallium oxide may range from about 4.4 eV to 4.9 eV, and a photodiode made of gallium oxide may absorb UV-C having a wavelength range of about 100 nm to about 280 nm.

As such, when UV-C is detected by the ultraviolet sensor 12 inside the electronic control apparatus 10, occurrence of a spark or arc may be determined.

The ultraviolet sensor 12 may output an electrical signal (hereinafter, referred to as an ‘ultraviolet detected signal’) corresponding to detection of ultraviolet light to the processor 16. As shown in FIG. 2, while no UV-C is irradiated onto the photodiode, the ultraviolet sensor 12 may output a ‘Low’ signal that is close to ‘0’ V. In contrast, when UV-C is irradiated onto the photodiode at time ‘0’, the ultraviolet sensor 12 may output a ‘High’ signal, that is, an ultraviolet detected signal.

The ultraviolet sensor 12 may include a plurality of ultraviolet sensors positioned at different locations. For example, the ultraviolet sensor 12 may include a first ultraviolet sensor 610 installed around a power receiving terminal of the power circuit 15 for receiving power from an external power source, and a second ultraviolet sensor 620 installed around a power supply terminal for supplying motor driving current to the motor 30. The first ultraviolet sensor 610 and the second ultraviolet sensor 620 may have the substantially same structure and function although being installed at different locations.

The valve driving circuit 13 may receive a control signal from the processor 16, and control valve driving current for driving the valve 20 in response to the control signal from the processor 16. For example, the valve driving circuit 13 may control valve driving current to open the valve 20 in response to an open signal from the processor 16. Also, the valve driving circuit 13 may control valve driving current to close the valve 20 in response to a close signal from the processor 16.

The valve driving circuit 13 may include a switching circuit for controlling valve driving current that is to be supplied to the valve 20. The switching circuit may include a transistor that is turned on/off in response to a control signal from the processor 16.

The motor driving circuit 14 may receive a control signal from the processor 16, and control motor driving current for driving the motor 30 in response to the control signal from the processor 16. The motor driving circuit 14 may control motor driving current to increase hydraulic pressure of the hydraulic pressure supply in response to a compression signal from the processor 16. Also, the motor driving circuit 14 may control motor driving current to decrease hydraulic pressure of the hydraulic pressure supply in response to a decompression signal from the processor 16.

The motor driving circuit 14 may include an inverter circuit or a H-bridge circuit for controlling motor driving current that is to be supplied to the motor 30. The inverter circuit or the H-bridge circuit may include a plurality of transistors that are turned on/off in response to a control signal from the processor 16.

The power circuit 15 may receive original power from an external power source and convert a voltage of the original power. The power circuit 15 may provide power with the converted voltage to the pedal sensor 11, the ultraviolet sensor 12, the valve driving circuit 13, the motor driving circuit 14, and/or the processor 16.

The power circuit 15 may convert the original power into power with a plurality of different voltages. For example, the power circuit 15 may convert the voltage of the original power into a first voltage that is suitable for the pedal sensor 11, the ultraviolet sensor 12, and/or the processor 16, and may also convert the voltage of the original power into a second voltage that is suitable for the valve driving circuit 13 and/or the motor driving circuit 14.

The power circuit 15 may include, for example, at least one Direct Current (DC)-DC converter or at least one regulator. The DC-DC converter may include at least one inductor and at least one capacitor. The regulator may include a breakdown diode.

Also, the power circuit 15 may be controlled by a control signal from the processor 16. For example, the power circuit 15 may block reception of original power according to a control signal from the processor 16, or block power that is to be supplied to the valve driving circuit 13 and/or the motor driving circuit 14 according to a control signal from the processor 16.

The processor 16 may receive a pedal signal of the pedal sensor 11 and an ultraviolet detected signal of the ultraviolet sensor 12, provide a valve control signal to the valve driving circuit 13, provide a motor control signal to the motor driving circuit 14, and provide a power control signal to the power circuit 15.

The processor 16 may provide a valve control signal and a motor control signal to the valve driving circuit 13 and the motor driving circuit 14, respectively, based on the pedal signal of the pedal sensor 11. For example, the processor 16 may provide a valve control signal and a motor control signal to the valve driving circuit 13 and the motor driving circuit 14, respectively, to supply hydraulic pressure to the wheel cylinders based on the pedal sensor 11 corresponding to the driver's braking start intention. Also, the processor 16 may provide a valve control signal and a motor control signal to the valve driving circuit 13 and the motor driving circuit 14, respectively, to retrieve hydraulic pressure of the wheel cylinders based on the pedal sensor 11 corresponding to the driver's braking stop intention.

The processor 16 may provide a power control signal to the power circuit 15 based on an ultraviolet detected signal of the ultraviolet sensor 12. For example, the processor 16 may control the power circuit 15 to block power reception from an external power source, in response to an ultraviolet detected signal of the first ultraviolet sensor 610 installed around the power receiving terminal. Also, the processor 16 may control the power circuit 15 to block power supply to the valve 20 and/or the motor 30, in response to an ultraviolet detected signal of the second ultraviolet sensor 620 installed around the power supply terminal. According to another example, the processor 16 may provide a warning message to the driver through a display or speaker of the vehicle, in response to an ultraviolet detected signal of the first ultraviolet sensor 610 installed around the power receiving terminal.

As described above, the electronic control apparatus 10 may detect a spark and/or arc occurred inside the electronic control apparatus 10 through the ultraviolet sensor 12, and control power that is to be supplied to the electronic control apparatus 10 based on the detection of the spark and/or arc. Also, the electronic control apparatus 10 may provide a warning message to the driver through the display or speaker of the vehicle based on the detection of the spark and/or arc. Accordingly, a fire caused by the spark and/or arc may be prevented from spreading from the electronic control apparatus 10 to other components of the vehicle.

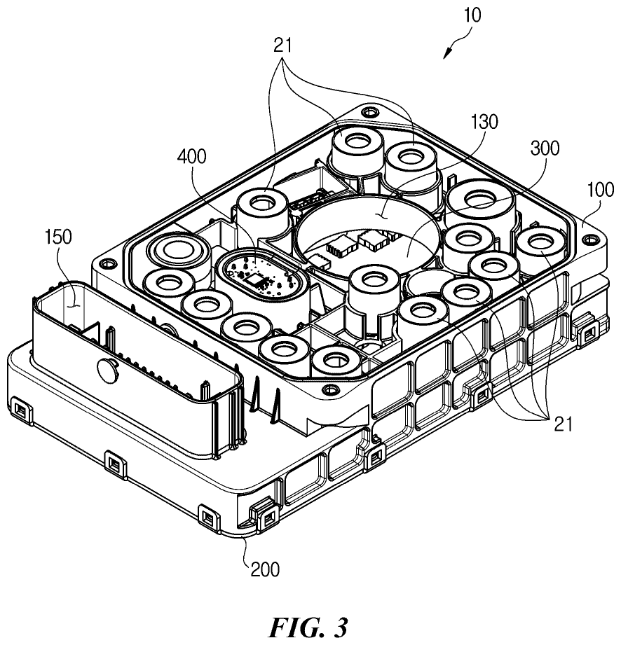

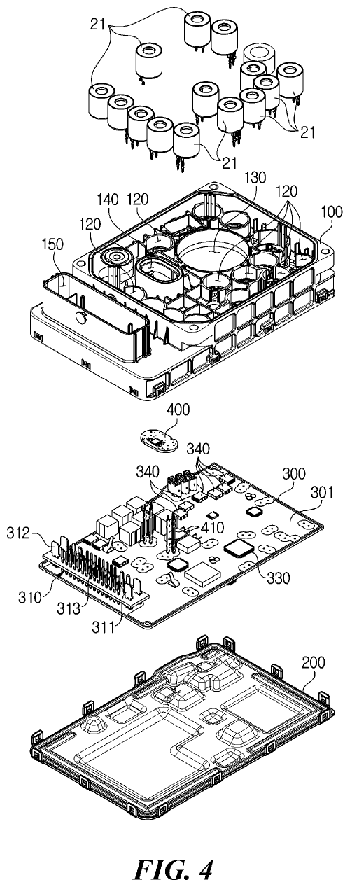

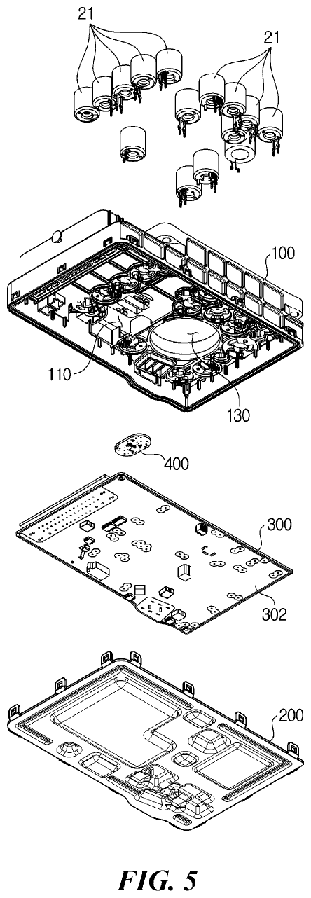

FIG. 3 shows an outer appearance of an electronic control apparatus and a valve according to an embodiment. FIG. 4 is an exploded perspective view of an electronic control apparatus and a valve according to an embodiment, shown in one direction. FIG. 5 is an exploded perspective view of an electronic control apparatus and a valve according to an embodiment, shown in another direction.

As shown in FIGS. 3, 4, and 5, the electronic control apparatus 10 and the plurality of valves 20 may be provided.

The electronic control apparatus 10 may include a housing 100, a cover 200, a first printed circuit board 300, and a second printed circuit board 400. The housing 100, the cover 200, and the printed circuit board 400 shown in FIGS. 3, 4, and 5 may not be essential components of the electronic control apparatus 10, and at least some of the housing 100, the cover 200, and the second printed circuit board 400 may be omitted.

The housing 100 may form an outer appearance of the electronic control apparatus 10 together with the cover 200, and protect the first printed circuit board 300 and the second printed circuit board 400 from outside. Particularly, the housing 100 may seal an inside space from the outside together with the cover 200, and accordingly, external foreign materials such as moisture may be prevented from entering the electronic control apparatus 10.

On one surface of the housing 100, an accommodating space 110 that accommodates the first printed circuit board 300 and the second printed circuit board 400 may be formed, and a side of the accommodating space 110 may open. The open side of the accommodating space 110 may be sealed by the cover 200.

In an outer side of the accommodating space 110 formed in the housing 100, a plurality of valve coils 21 constituting the plurality of valves 20 may be provided. On an opposite surface (hereinafter, referred to as ‘another surface’) of the one surface of the housing 100 on which the accommodating space 110 is formed, a plurality of resting spaces 120 may be provided.

The plurality of valve coils 21 may be respectively rested in the plurality of resting spaces 120 formed on the other surface of the housing 100. Both terminals of each of the plurality of valve coils 21 may penetrate the housing 100 from the other surface of the housing 100 to the one surface of the housing 100 through a through hole formed in the housing 100. In other words, both terminals of each of the plurality of valve coils 21 may extend from the resting space 120 of the housing 100 to the accommodating space 110 of the housing 110. Accordingly, both terminals of each of the plurality of valve coils 21 may be electrically connected to the first printed circuit board 300 accommodated in the accommodating space 110 of the housing 100.

A first hollow part 130 may be formed in a substantially central part of the housing 100. A pump not shown in FIGS. 3, 4, and 5 may be rested in the first hollow part 130.

Also, a second hollow part 140 may be formed in a substantially central part of the housing 100. The second printed circuit board 400 may be provided in the second hollow part 140. The second printed circuit board 400 may be exposed to the outside of the housing 100 through the second hollow part 140.

In a side of the housing 100, a connecting hole 150 connecting the accommodating space 110 to the outside of the housing 100 may be formed. In the connecting hole 150, a first connector 310 for receiving power from an external power source and connecting to a communication network for vehicle may be provided. The first connector 310 may be connected to the first printed circuit board 300 and exposed to the outside of the housing 100 through the connecting hole 150.

The first connector 310 may include a power pin 311 for receiving power from an external power source and a ground pin 312, and further include a communication pin 313 for connecting to the communication network for vehicle. A voltage of original power may be applied between the power pin 311 and the ground pin 312. Also, current of original power may flow in through the power pin 311 and flow out through the ground pin 312. The power pin 311 and the ground pin 312 may be insulated by air.

The cover 200 may seal the accommodating space 110 of the housing 100 in which the first printed circuit board 300 and the second printed circuit board 400 are accommodated. For example, the accommodating space 110 may be provided in a lower portion of the housing 100 with reference to FIGS. 4 and 5, and the cover 200 may be provided below the housing 100 to close the accommodating space 110 that opens from below.

As shown in FIGS. 4 and 5, the cover 200 may be hooked to the housing 100, although not limited thereto. For example, the cover 200 may be coupled to the housing 100 through a screw, or the cover 200 may be fitted into the housing 100.

The second printed circuit board 400 may be provided in the second hollow part 140 of the housing 100 and exposed to the outside through the second hollow part 140.

The pedal sensor 11 for detecting a movement of the brake pedal may be provided on the second printed circuit board 400. For example, the brake pedal may be provided with a magnet moving together with the brake pedal, and the pedal sensor 11 may include a hall sensor for detecting a magnetic field generated by the magnet. Also, the pedal sensor 11 of the second printed circuit board 400 may be exposed to the outside through the second hollow part 140 of the housing 100.

The second printed circuit board 400 may be electrically connected to the first printed circuit board 300 through a plurality of pins 410. A pedal signal from the pedal sensor 11 may be provided to the processor 16 mounted on the first printed circuit board 300 through the plurality of pins 410 of the second printed circuit board 400.

The first printed circuit board 300 may be provided in the accommodating space 110 of the housing 100.

On the first printed circuit board 300, electrical components and/or electronic components for implementing functions of the electronic control apparatus 10 may be mounted.

The first printed circuit board 300 may be provided with a first connector 310 for receiving power from an external power source and connecting to the communication network for vehicle. The first connector 310 may be exposed to the outside through the connecting hole 150 of the housing 100.

A capacitor and an inductor constituting the power circuit 15 may be mounted on the first printed circuit board 300. The capacitor and the inductor may constitute a DC-DC converter for converting a voltage of original power.

The processor 16 for controlling braking of the vehicle may be mounted on the first printed circuit board 300. The processor 16 may provide the valve driving circuit 13 and/or the motor driving circuit 14 with a control signal for controlling the valve 20 and/or the motor 30 based on a pedal signal from the pedal sensor 11.

An Application-Specific Integrated Circuit (ASIC) 330 for implementing the valve driving circuit 13 may be mounted on the first printed circuit board 300. The ASIC 330 may be provided with a plurality of switching circuits for allowing or blocking valve driving current that is to be supplied to the plurality of valves 20.

A plurality of switching devices 340 for implementing the motor driving circuit 14 may be mounted on the first printed circuit board 300. Each of the plurality of switching devices 340 may include, for example, a Metal Oxide Semiconductor Field Effect Transistor (MOSFET), a Bipolar Junction Transistor (BJT), or an Insulated Gate Bipolar Transistor (IGBT). The plurality of switching devices 340 may constitute, for example, an inverter circuit or a H-bridge circuit.

The first printed circuit board 300 may be provided with a second connector 320 for providing motor driving current to the motor 30. The second connector 320 may be connected to a plurality of terminals of the motor 30.

The ultraviolet sensor 12 for detecting UV-C emitted by a spark or arc may be mounted on the first printed circuit board 300. The ultraviolet sensor 12 may detect UV-C and output an ultraviolet detected signal to the processor 16 in response to the detection of UV-C.

The ultraviolet sensor 12 may include the first ultraviolet sensor 610 and the second ultraviolet sensor 620 mounted on a first surface 301 of the first printed circuit board 300, and a third ultraviolet sensor 630 and a fourth ultraviolet sensor 640 mounted on a second surface 302 of the first printed circuit board 300. The ultraviolet sensor 610, the second ultraviolet sensor 620, the third ultraviolet sensor 630, and the fourth ultraviolet sensor 640 may have the same structure and function and be positioned at different locations.

Hereinafter, examples of structures of the ultraviolet sensor 12 will be described.

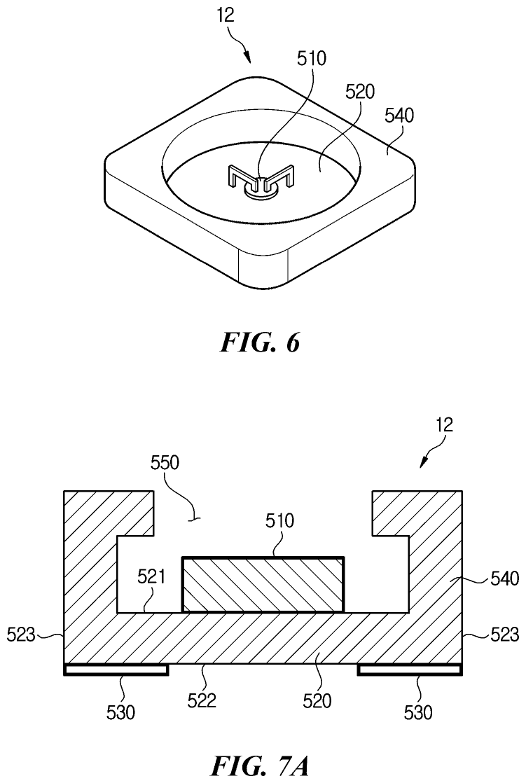

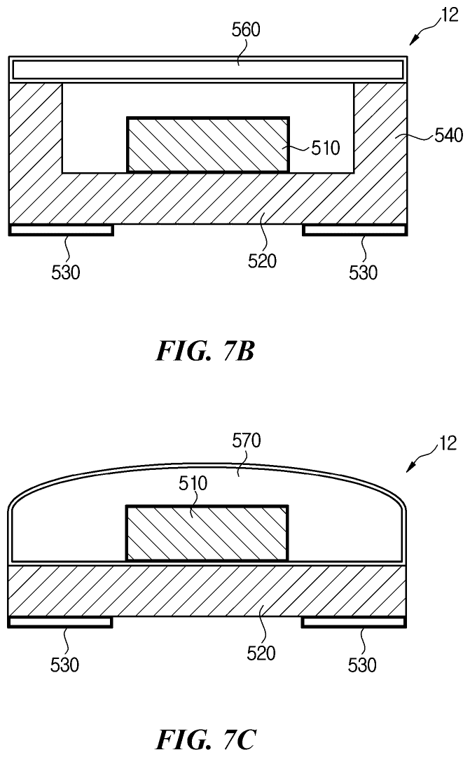

FIG. 6 shows an example of an ultraviolet sensor included in an electronic control apparatus according to an embodiment. FIGS. 7A, 7B, and 7C show structures of ultraviolet sensors included in an electronic control apparatus according to an embodiment.

As shown in FIGS. 6 and 7A, the ultraviolet sensor 12 may include a photodiode 510, a sensor substrate 520, a lower connection terminal 530, and a side wall 540.

The photodiode 510 may absorb ultraviolet light, particularly, UV-C having a wavelength range of about 100 nm to about 280 nm, and output an electrical signal (for example, a voltage signal or current signal) in response to the absorption of UV-C. The photodiode 510 may be, as described above, made of a semiconductor material capable of absorbing, for example, UV-C. For example, the photodiode 510 may include a PN junction diode made of gallium oxide (Ga₂O₃), gallium nitride (GaN), silicon carbide (SiC), or diamond (C).

The sensor substrate 520 may support the photodiode 510. Referring to FIG. 7A, the photodiode 510 may be provided on an upper surface 521 of the sensor substrate 520. Also, referring to FIG. 7A, the lower connecting terminal 530 may be formed on a lower surface 522 of the sensor substrate 520.

The sensor substrate 520 may electrically connect the photodiode 510 to the lower connection terminal 530. The sensor substrate 520 may be made of, for example, a non-conductive material, and include conductive signal lines extending from the photodiode 510 to the lower connecting terminal 530. Power may be supplied from the lower connecting terminal 530 to the photodiode 510 through the conductive signal lines, and an ultraviolet detected signal may be transferred from the photodiode 510 to the lower connecting terminal 530 through the conductive signal lines.

The lower connecting terminal 530 may be provided on the lower surface 522 which is opposite to the upper surface of the sensor substrate 520 on which the photodiode 510 is provided.

The lower connecting terminal 530 may be electrically connected to the photodiode 510 through the conductive signal lines of the sensor substrate 520. According to mounting of the ultraviolet sensor 12 on the first printed circuit board 300, the lower connecting terminal 530 may be electrically connected to the first printed circuit board 300. Accordingly, the photodiode 520 may be electrically connected to the first printed circuit board 300 through the lower connecting terminal 530, and electrically connected to the processor 16 through the first printed circuit board 300.

As such, because the lower connecting terminal 530 is provided on the lower surface 522 of the sensor substrate 520, the photodiode 510 of the ultraviolet sensor 12 mounted on the first printed circuit board 300 may face upward from the first printed circuit board 300.

The side wall 540 may be provided at a side surface of the sensor substrate 520. The side wall 540 may have a cylindrical shape or a polygonal pillar shape. The side wall 540 may surround the photodiode 510 and protect the photodiode 510 from an external foreign material or an external force. The side wall 540 may be integrated into the sensor substrate 520.

Referring to FIG. 7A, an opening 550 through which ultraviolet light arrives at the photodiode 510 may be formed in an upper side of the ultraviolet sensor 12. Ultraviolet light may be irradiated onto the photodiode 510 through the opening 550. The opening 550 may be aligned in the same direction as the photodiode 510 with respect to the sensor substrate 520. Therefore, according to mounting of the ultraviolet sensor 12 on the first printed circuit board 300, the opening 550 and the photodiode 510 may face upward from the first printed circuit board 300. Also, ultraviolet light generated above the first printed circuit board 300 may be irradiated onto the photodiode 510 through the opening 550.

The structure of the ultraviolet sensor 12 is not limited to that shown in FIG. 7A.

As shown in FIG. 7B, the ultraviolet sensor 12 may include a photodiode 510, a sensor substrate 520, a lower connecting terminal 530, a side wall 540, and a transparent cover 560.

The photodiode 510, the sensor substrate 520, the lower connecting terminal 530, and the side wall 540 may be the same as the photodiode, the sensor substrate, the lower connecting terminal, and the side wall described with reference to FIG. 7A.

The transparent cover 560 may be provided on an upper surface of the ultraviolet sensor 12 with reference to FIG. 7B. The transparent cover 560 may cover the opening 550 of the ultraviolet sensor 12 from above. The transparent cover 560 may protect the photodiode 510 from an external foreign material or an external force, and also the transparent cover 560 may allow ultraviolet light to arrive at the photodiode 510. The transparent cover 560 may be made of, for example, a sapphire plate.

As shown in FIG. 7C, the ultraviolet sensor 12 may include a photodiode 510, a sensor substrate 520, a lower connecting terminal 530, and a transparent dome 570.

The sensor substrate 520 and the lower connecting terminal 530 may be the same as the sensor substrate and the lower connecting terminal described with reference to FIG. 7A.

The transparent dome 570 may cover the photodiode 510. The transparent dome 570 may prevent or suppress damage to the photodiode 510 due to an external mechanical action and/or damage to the photodiode 510 due to a chemical action.

The transparent dome 570 may be made of silicon or an epoxy resin. For example, molten silicon or a molten epoxy resin may be discharged onto the photodiode 510 through a nozzle, etc., and the discharged silicon or epoxy resin may be hardened to form the transparent dome 570.

Hereinafter, examples of structures of the ultraviolet sensor 12 will be described.

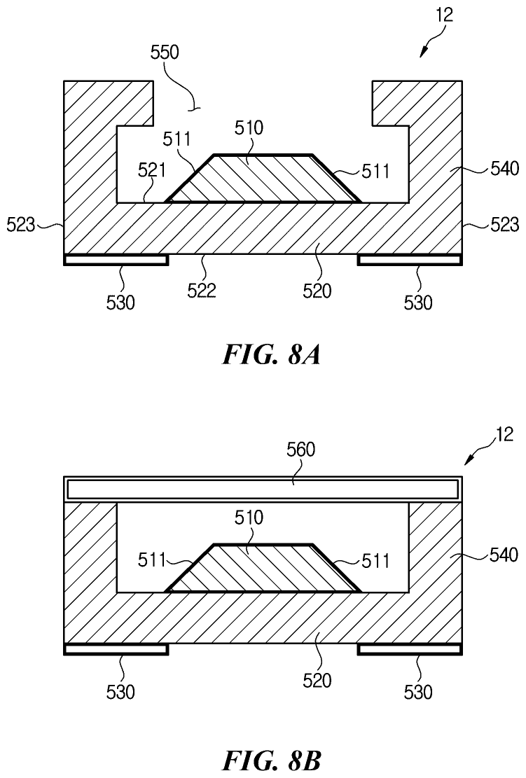

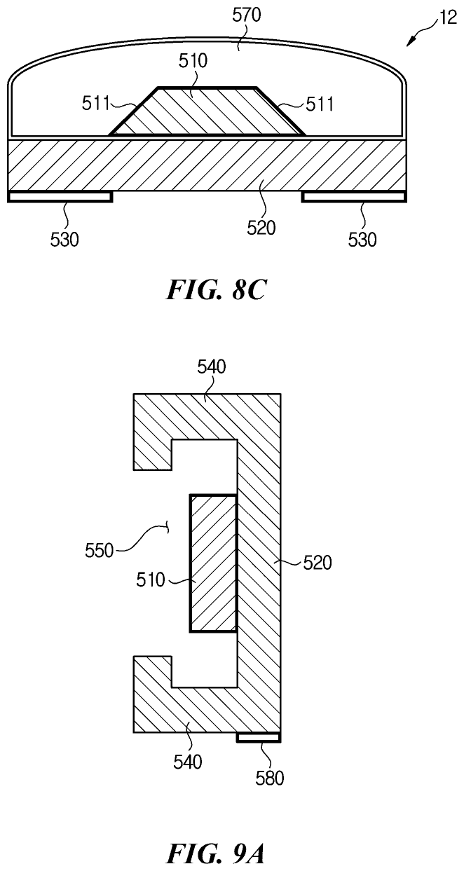

FIGS. 8A, 8B, and 8C show structures of ultraviolet sensors included in an electronic control apparatus according to an embodiment.

As shown in FIG. 8A, the ultraviolet sensor 12 may include a photodiode 510, a sensor substrate 520, a lower connecting terminal 530, and a side wall 540. The sensor substrate 520, the lower connecting terminal 530, and the side wall 540 may be the same as the sensor substrate, the lower connecting terminal, and the side wall described with reference to FIG. 7A.

The photodiode 510 may include an inclined surface 511. The photodiode 510 may absorb ultraviolet light through the inclined surface 511. Accordingly, the photodiode 510 may detect ultraviolet light generated in a side direction of the ultraviolet sensor 12 through the inclined surface 511.

As shown in FIG. 8B, the ultraviolet sensor 12 may include a photodiode 510, a sensor substrate 520, a lower connecting terminal 530, a side wall 540, and a transparent cover 560. The sensor substrate 520, the lower connecting terminal 530, the side wall 540, and the transparent cover 560 may be the same as the sensor substrate, the lower connecting terminal, the side wall, and the transparent cover shown in FIG. 7B.

The photodiode 510 may include an inclined surface 511. The photodiode 510 may absorb ultraviolet light through the inclined surface 511. Accordingly, the photodiode 510 may detect ultraviolet light generated in the side direction of the ultraviolet sensor 12 through the inclined surface 511.

As shown in FIG. 8C, the ultraviolet sensor 12 may include a photodiode 510, a sensor substrate 520, a lower connecting terminal 530, and a transparent dome 570. The photodiode 510, the sensor substrate 520, the lower connecting terminal 530, and the transparent dome 570 may be the same as the photodiode, the sensor substrate, the lower connecting terminal, and the transparent dome shown in FIG. 7C.

By the transparent dome 570, ultraviolet light generated in the side direction of the ultraviolet sensor 12 with reference to FIG. 8C may arrive at the photodiode 510 by passing through the transparent dome 570. To absorb ultraviolet light passed through the transparent dome 570 in the side direction, the photodiode 510 may include an inclined surface 511. The photodiode 510 may detect ultraviolet light generated in the side direction of the ultraviolet sensor through the inclined surface 511.

Hereinafter, examples of structures of the ultraviolet sensor 12 will be described.

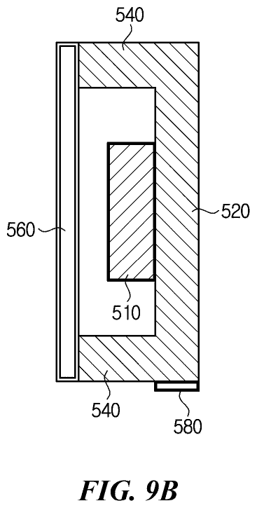

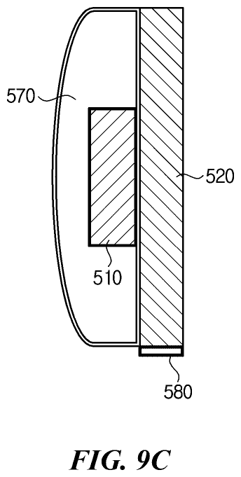

FIGS. 9A, 9B, and 9C show structures of ultraviolet sensors included in an electronic control apparatus according to an embodiment.

As shown in FIG. 9A, the ultraviolet sensor 12 may include a photodiode 510, a sensor substrate 520, a side connecting terminal 580, and a side wall 540.

The photodiode 510, the sensor substrate 520, and the side wall 540 may be the same as the photodiode, the sensor substrate, and the side wall shown in FIG. 7A.

The photodiode 510 may be provided on an upper surface 521 of the sensor substrate 520, and the side connecting terminal 580 may be provided on a side surface of the sensor substrate 520. Also, the side connecting terminal 580 may be provided on a side wall of the side wall 540 integrated into the sensor substrate 520.

The side connecting terminal 580 may be electrically connected to the photodiode 510 through a conductive signal line of the sensor substrate 520. Also, according to mounting of the ultraviolet sensor 12 on the first printed circuit board 300, the side connecting terminal 580 may be electrically connected to the first printed circuit board 300. Accordingly, the photodiode 510 may be electrically connected to the processor 16 through the side connecting terminal 580 and the first printed circuit board 300.

As such, because the side connecting terminal 580 is provided on the side surface 523 of the sensor substrate 520, the photodiode 510 of the ultraviolet sensor 12 mounted on the first printed circuit board 300 may be toward a side direction of the first printed circuit board 300.

Also, an opening 550 may be aligned in the same direction as the photodiode 510 with respect to the sensor substrate 520. Therefore, according to mounting of the ultraviolet sensor 12 on the first printed circuit board 300, the opening 550 and the photodiode 510 may be toward the side direction of the first printed circuit board 300. Also, ultraviolet light generated on the first printed circuit board 300 may be irradiated onto the photodiode 510 through the opening 550.

As shown in FIG. 9B, the ultraviolet sensor 12 may include a photodiode 510, a sensor substrate 520, a side connecting terminal 580, a side wall 540, and a transparent cover 560.

The photodiode 510, the sensor substrate 520, the side wall 540, and the transparent cover 560 may be the same as the photodiode, the sensor substrate, the side wall, and the transparent cover described in FIG. 7B.

The photodiode 510 may be provided on an upper surface 521 of the sensor substrate 520, and the side connecting terminal 580 may be provided on a side surface 523 of the sensor substrate 520. Also, the side connecting terminal 580 may be provided on a side wall of the side wall 540 integrated into the sensor substrate 520.

As such, because the side connecting terminal 580 is provided on the side surface 523 of the sensor substrate 520, the photodiode 510 of the ultraviolet sensor 12 mounted on the first printed circuit board 300 may be toward the side direction of the first printed circuit board 300. Also, ultraviolet light generated on the first printed circuit board 300 may be irradiated onto the photodiode 510.

As shown in FIG. 9C, the ultraviolet sensor 12 may include a photodiode 510, a sensor substrate 520, a side connecting terminal 580, and a transparent dome 570.

The photodiode 510, the sensor substrate 520, and the transparent dome 570 may be the same as the photodiode, the sensor substrate, and the transparent dome described with reference to FIG. 7C.

The photodiode 510 may be provided on an upper surface 521 of the sensor substrate 520, and the side connecting terminal 580 may be provided on a side surface 523 of the sensor substrate 520.

As such, because the side connecting terminal 580 is provided on the side surface 523 of the sensor substrate 520, the photodiode 510 of the ultraviolet sensor 12 mounted on the first printed circuit board 300 may be toward the side direction of the first printed circuit board 300. Also, ultraviolet light generated on the first printed circuit board 300 may be irradiated onto the photodiode 510.

Hereinafter, examples of structures of the ultraviolet sensor 12 will be described.

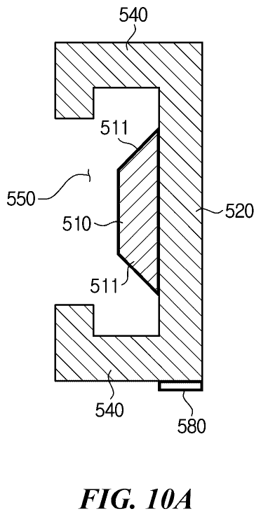

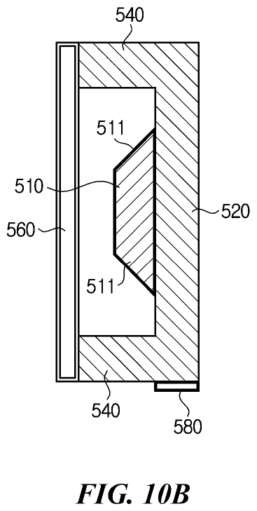

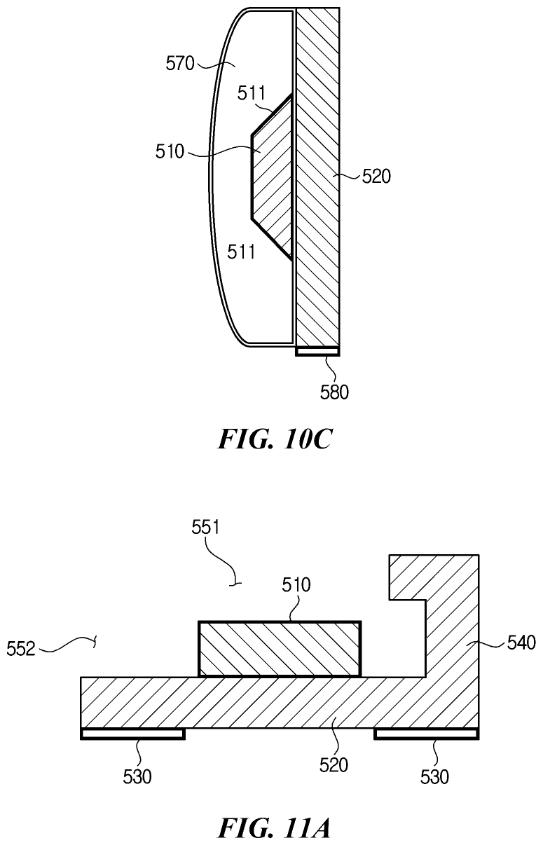

FIGS. 10A, 10B, and 10C show structures of ultraviolet sensors included in an electronic control apparatus according to an embodiment.

As shown in FIG. 10A, the ultraviolet sensor 12 may include a photodiode 510, a sensor substrate 520, a side connecting terminal 580, and a side wall 540. The sensor substrate 520, the side connecting terminal 580, and the side wall 540 may be the same as the sensor substrate, the side connecting terminal, and the side wall shown in FIG. 9A. Also, the photodiode 510 may include an inclined surface 511, and absorb ultraviolet light through the inclined surface 511.

As shown in FIG. 10B, the ultraviolet sensor 12 may include a photodiode 510, a sensor substrate 520, a side connecting terminal 580, a side wall 540, and a transparent cover 560. The sensor substrate 520, the side connecting terminal 580, the side wall 540, and the transparent cover 560 may be the same as the sensor substrate, the side connecting terminal, the side wall, and the transparent cover shown in FIG. 9B. Also, the photodiode 510 may include an inclined surface 511, and absorb ultraviolet light through the inclined surface 511.

As shown in FIG. 10C, the ultraviolet sensor 12 may include a photodiode 510, a sensor substrate 520, a side connecting terminal 580, and a transparent dome 570. The sensor substrate 520, the side connecting terminal 580, and the transparent dome 570 may be the same as the sensor substrate, the side connecting terminal, and the transparent dome shown in FIG. 9C. Also, the photodiode 510 may include an inclined surface 511, and absorb ultraviolet light through the inclined surface 511.

Hereinafter, examples of structures of the ultraviolet sensor 12 will be described.

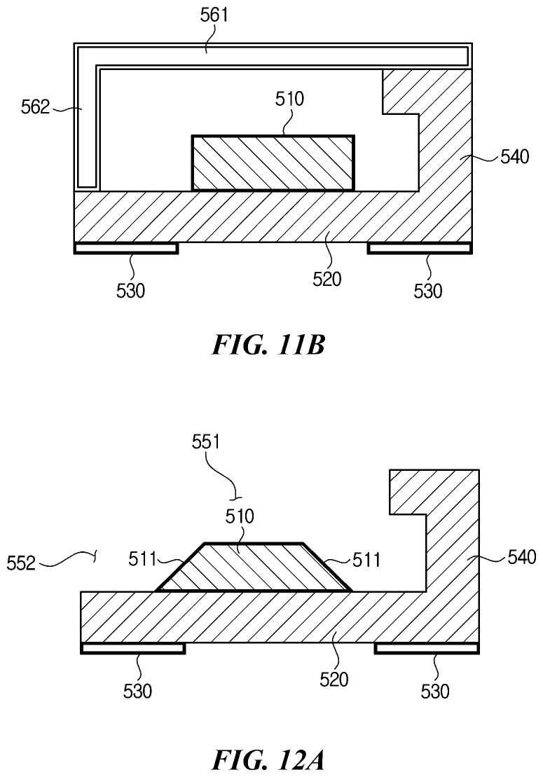

FIGS. 11A and 11B show structures of ultraviolet sensors included in an electronic control apparatus according to an embodiment.

As shown in FIG. 11A, the ultraviolet sensor 12 may include a photodiode 510, a sensor substrate 520, a lower connecting terminal 530, and a side wall 540.

The photodiode 510, the sensor substrate 520, and the lower connecting terminal 530 may be the same as the photodiode, the sensor substrate, and the lower connecting terminal shown in FIG. 7A.

The side wall 540 may be provided at a portion of a side surface of the sensor substrate 520, and a side opening 552 may be formed in at least one portion of the side surface of the sensor substrate 520. In other words, an upper opening 551 may be formed above the photodiode 510, and a side opening 552 may be formed toward a side surface of the photodiode 510.

As such, because the side opening 552 is formed toward at least one portion of the side surface of the sensor substrate 520, ultraviolet light generated on the first printed circuit board 300 may be irradiated onto the photodiode 510 through the side opening 552 of the side surface.

As shown in FIG. 11B, the ultraviolet sensor 12 may include a photodiode 510, a sensor substrate 520, a lower connecting terminal 530, a side wall 540, and a transparent substrate 560.

The photodiode 510, the sensor substrate 520, and the lower connecting terminal 530 may be the same as the photodiode, the sensor substrate, and the lower connecting terminal described with reference to FIG. 7B.

The side wall 540 may be provided at a portion of a side surface of the sensor substrate 520, and a side transparent cover 562 may be provided toward at least one portion of the side surface of the sensor substrate 520. An upper transparent cover 561 may be provided above the photodiode 510, and the side transparent cover 562 may be provided toward the side surface of the photodiode 510.

As such, because the side transparent cover 562 is provided toward at least one portion of the side surface of the sensor substrate 520, ultraviolet light generated on the first printed circuit board 300 may be irradiated onto the photodiode 510 through the side transparent cover 562 of the side surface.

Hereinafter, examples of structures of the ultraviolet sensor 12 will be described.

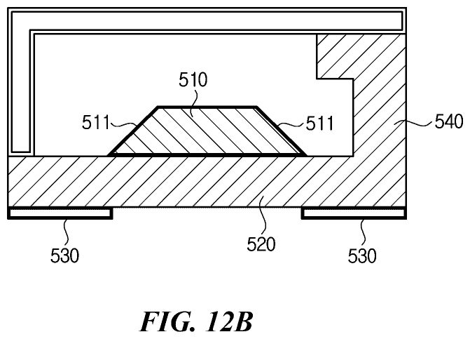

FIGS. 12A and 12B show structures of ultraviolet sensors included in an electronic control apparatus according to an embodiment.

As shown in FIG. 12A, the ultraviolet sensor 12 may include a photodiode 510, a sensor substrate 520, a lower connecting terminal 530, and a side wall 540. The sensor substrate 520, the side connecting terminal 530, and the side wall 540 may be the same as the sensor substrate, the side connecting terminal, and the side wall shown in FIG. 11A. Also, the photodiode 510 may include an inclined surface 511, and absorb ultraviolet light through the inclined surface 511.

As shown in FIG. 12B, the ultraviolet sensor 12 may include a photodiode 510, a sensor substrate 520, a lower connecting terminal 530, a side wall 540, and a transparent substrate 560. The sensor substrate 520, the lower connecting terminal 530, the side wall 540, and the transparent cover 560 may be the same as the sensor substrate, the lower connecting terminal, the side wall, and the transparent cover described with reference to FIG. 11B. Also, the photodiode 510 may include an inclined surface 511, and absorb ultraviolet light through the inclined surface 511.

Hereinafter, an example of a position of the ultraviolet sensor 12 will be described.

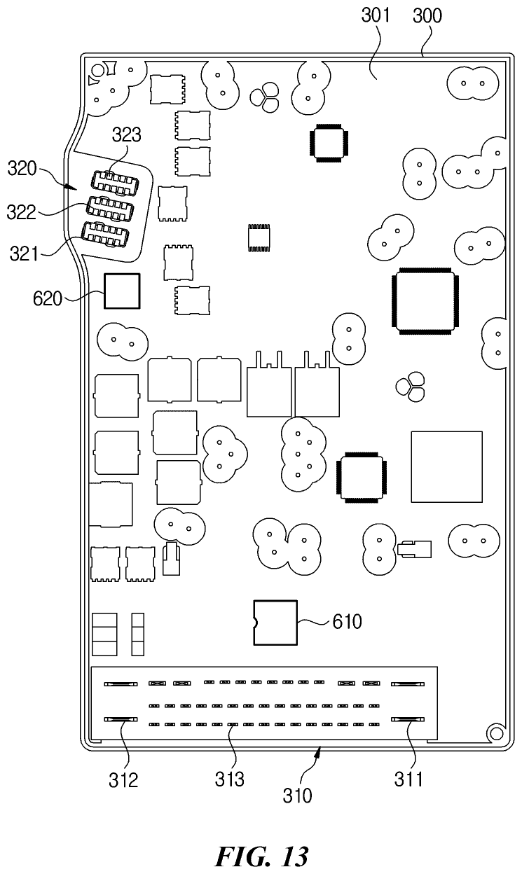

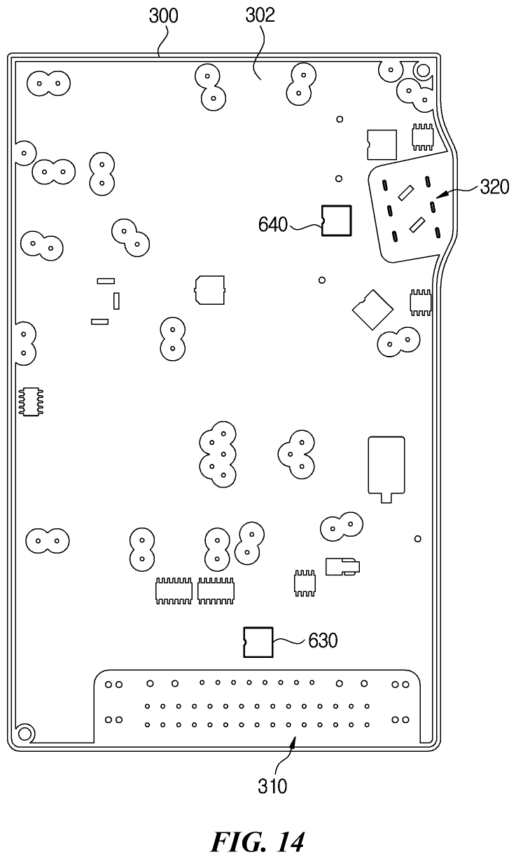

FIG. 13 shows a first surface of a first printed circuit board included in an electronic control apparatus according to an embodiment. FIG. 14 shows a second surface of a first printed circuit board included in an electronic control apparatus according to an embodiment.

As described above, the ultraviolet sensor 12 may include the first ultraviolet sensor 610 and the second ultraviolet sensor 620 mounted on the first surface 301 of the first printed circuit board 300, and the third ultraviolet sensor 630 and the fourth ultraviolet sensor 640 mounted on the second surface 302 of the first printed circuit board 300. The first ultraviolet sensor 610, the second ultraviolet sensor 620, the third ultraviolet sensor 630, and the fourth ultraviolet sensor 640 may have the same structure and function, and be different in position.

As shown in FIG. 13, the first ultraviolet sensor 610 may be provided around the first connector 310 on the first surface 301 of the first printed circuit board 300.

Original power supplied to the electronic control apparatus 10 may be provided to the power circuit 15 through the first connector 310. The first connector 310 may further include the power pin 311 for receiving power from an external power source, and the ground pin 312, and further include the communication pin 313 for connecting to the communication network for vehicle.

A voltage of the original power may be applied between the power pin 311 and the ground pin 312, and current of the original power may flow in through the power pin 311 and flow out through the ground pin 312.

In this case, due to a sudden supply of original power, a sudden rise in voltage of original power, or a sudden rise in current of original power, insulation between the power pin 311 and the ground pin 312, between the power pin 311 and the communication pin 313, or between the power pin 311 and the first printed circuit board 300 may break down. A very strong electric field may be generated between the power pin 311 and the ground pin 312, between the power pin 311 and the communication pin 313, or between the power pin 311 and the first printed circuit board 300, and due to the very strong electric field, direct movements of charges between the power pin 311 and the ground pin 312, between the power pin 311 and the communication pin 313, or between the power pin 311 and the first printed circuit board 300 may occur. Due to the movements of charges between the power pin 311 and the ground pin 312, between the power pin 311 and the communication pin 313, or between the power pin 311 and the first printed circuit board 300, a spark or arc may occur. The above description about spark or arc occurrence is only an example, and due to various causes, a spark or arc may occur between the power pin 311 and the ground pin 312, between the power pin 311 and the communication pin 313, between the ground pin 312 and the communication pin 313, between the power pin 311 and the first printed circuit board 300, or between the ground pin 312 and the first printed circuit board 300.

As such, due to various causes, a spark or arc may occur in the first connector 310 on the first surface 301, and the spark or arc may include emission of UV-C.

The first ultraviolet sensor 610 may be positioned around the first connector 310 on the first surface 301 in order to stably detect UV-C generated by a spark or arc. For example, the first ultraviolet sensor 610 may be an electrical/electronic device positioned closet to the first connector 310 on the first surface 301. According to another example, a shortest distance between the first ultraviolet sensor 610 and the first connector 310 on the first surface 301 may be less than a maximum distance between the pins 311, 312, and 313 constituting the first connector 310. According to another embodiment, the shortest distance between the first ultraviolet sensor 610 and the first connector 310 on the first surface 301 may be less than a minimum distance between both ends of the first printed circuit board 300. According to another example, the shortest distance between the first ultraviolet sensor 610 and the first connector 310 on the first surface 301 may be less than half a maximum distance between both ends of the first printed circuit board 300.

Also, the first ultraviolet sensor 610 may be positioned such that the opening 550 of the first ultraviolet sensor 610 faces the first connector 310. Accordingly, UV-C generated in the first connector 310 may be irradiated onto the photodiode 510 through the opening 550 of the first ultraviolet sensor 610.

As shown in FIG. 13, the second ultraviolet sensor 620 may be positioned around the second connector 320 on the first surface 301 of the first printed circuit board 300.

Motor driving power of the motor driving circuit 14 may be provided to the motor 30 through the second connector 320. The second connector 320 may include U-phase pins 321, V-phase pins 322, and W-phase pins 323 for providing motor driving current to the motor 30.

A voltage of motor driving power may be applied between at least 17 pins among the U-phase pins 321, the V-phase pins 321, and the W-phase pins 323. Also, current of motor driving power may flow into the motor 30 through at least one pin among the U-phase pins 321, the V-phase pins 321, and the W-phase pins 323, and flow out from the motor 30 through at least one pin among the U-phase pins 321, the V-phase pins 321, and the W-phase pins 323.

In this case, even when the motor driving circuit 15 is suddenly turned off, the motor 30 may continue to rotate without immediately stopping, due to inertia. By rotation of the motor 30, an electromotive force may be generated in a coil included in the motor 30, and the electromotive force may be applied between at least 17 pins among the U-phase pins 321, the V-phase pins 322, and the W-phase pins 323. Due to the electromotive force of the motor 30, insulation between the at least 17 pins among the U-phase pins 321, the V-phase pins 322, and the W-phase pins 323 may break down. A very strong electric field may be generated between the at least 17 pins among the U-phase pins 321, the V-phase pins 322, and the W-phase pins 323 due to the electromotive force of the motor 30, and due to the very strong electric field, direct movements of charges between the at least 17 pins among the U-phase pins 321, the V-phase pins 322, and the W-phase pins 323 may occur. The movements of charges between the at least 17 pins among the U-phase pins 321, the V-phase pins 322, and the W-phase pins 323 may cause a spark or arc. The above description about spark or arc occurrence is only an example, and due to various causes, a spark or arc may occur between the U-phase pins 321, the V-phase pins 322, and the W-phase pins 323.

As such, due to various causes, a spark or arc may occur in the second connector 320 on the first surface 301, and the spark or arc may include emission of UV-C.

The second ultrasonic sensor 620 may be positioned around the second connector 320 on the first surface 301 in order to stably detect UV-C generated by a spark or arc. For example, the second ultraviolet sensor 620 may be an electrical/electronic device positioned closest to the second connector 320 on the first surface 301. According to another example, a shortest distance between the second ultraviolet sensor 620 and the second connector 320 on the first surface 301 may be less than a maximum distance between the U-phase pins 321, the V-phase pins 322, and the W-phase pins 323 constituting the second connector 320. According to another example, the shortest distance between the second ultraviolet sensor 620 and the second connector 320 on the first surface 301 may be less than a minimum distance between both ends of the first printed circuit board 300. According to another example, the shortest distance between the second ultraviolet sensor 620 and the second connector 320 on the first surface 301 may be less than half a maximum distance between both ends of the first printed circuit board 300.

Also, the second ultraviolet sensor 620 may be positioned such that the opening 550 of the second ultraviolet sensor 620 faces the second connector 320. Accordingly, UV-C generated in the second connector 320 may be irradiated onto the photodiode 510 through the opening 550 of the second ultraviolet sensor 620.

As shown in FIG. 14, the third ultraviolet sensor 630 may be positioned around the first connector 310 on the second surface 302 of the first printed circuit board 300.

Due to the same case by which a spark or arc occurs in the first connector 310 on the first surface 301, as described above, a spark or arc may occur in the first connector 310 on the second surface 302, and the spark or arc may include emission of UV-C.

The third ultraviolet sensor 630 may be positioned around the first connector 310 on the second surface 302 in order to stably detect UV-C occurred by a spark or arc. For example, the third ultraviolet sensor 630 may be an electrical/electronic device positioned closet to the first connector 310 on the second surface 302. According to another example, a shortest distance between the third ultraviolet sensor 630 and the first connector 310 on the second surface 302 may be less than a maximum distance between the pins 311, 312, and 313 constituting the first connector 310. According to another example, the shortest distance between the third ultraviolet sensor 630 and the first connector 310 on the second surface 302 may be less than a minimum distance between both ends of the first printed circuit board 300. According to another embodiment, the shortest distance between the third ultraviolet sensor 630 and the first connector 310 on the second surface 302 may be less than half a maximum distance between both ends of the first printed circuit board 300.

Also, the third ultraviolet sensor 630 may be positioned such that the opening 550 of the third ultraviolet sensor 630 faces the first connector 310. Accordingly, UV-C generated in the first connector 310 may be irradiated onto the photodiode 510 through the opening 550 of the third ultraviolet sensor 630.

As shown in FIG. 14, the fourth ultraviolet sensor 640 may be positioned around the second connector 320 on the second surface 302 of the first printed circuit board 300.

Due to the same case by which a spark or arc occurs in the second connector 320 on the first surface 301, as described above, a spark or arc may occur in the second connector 320 on the second surface 302, and the spark or arc may include emission of UV-C.

The fourth ultrasonic sensor 640 may be positioned around the second connector 320 on the second surface 301 in order to stably detect UV-C generated by a spark or arc. For example, the fourth ultraviolet sensor 640 may be an electrical/electronic device positioned closest to the second connector 320 on the second surface 302. According to another example, a shortest distance between the fourth ultraviolet sensor 640 and the second connector 320 on the second surface 302 may be less than a maximum distance between the U-phase pins 321, the V-phase pins 322, and the W-phase pins 323 constituting the second connector 320. According to another example, the shortest distance between the fourth ultraviolet sensor 640 and the second connector 320 on the second surface 302 may be less than a minimum distance between both ends of the first printed circuit board 300. According to another example, the shortest distance between the fourth ultraviolet sensor 640 and the second connector 320 on the first surface 301 may be less than half a maximum distance between both ends of the first printed circuit board 300.

Also, the fourth ultraviolet sensor 640 may be positioned such that the opening 550 of the fourth ultraviolet sensor 640 faces the second connector 320. Accordingly, UV-C generated in the second connector 320 may be irradiated onto the photodiode 510 through the opening 550 of the fourth ultraviolet sensor 640.

Hereinafter, an example of a position of the ultraviolet sensor 12 will be described.

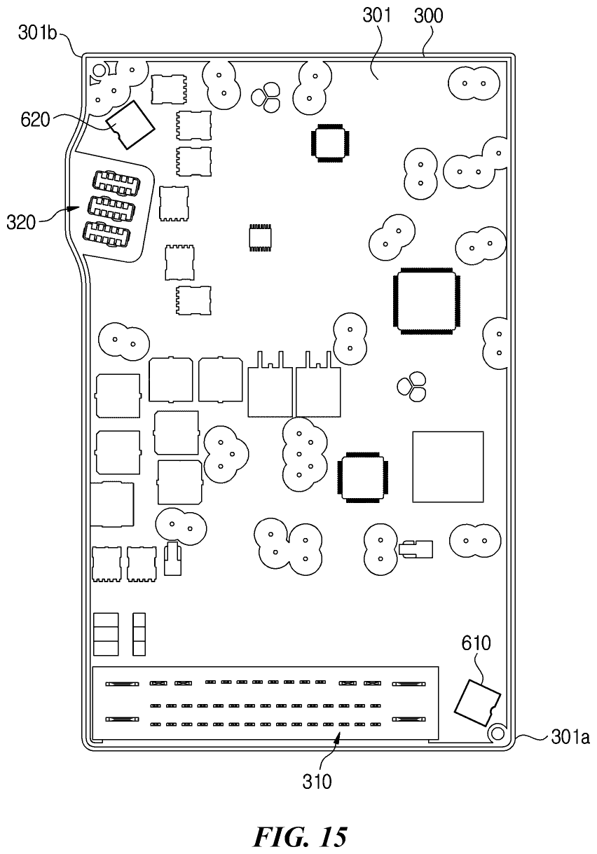

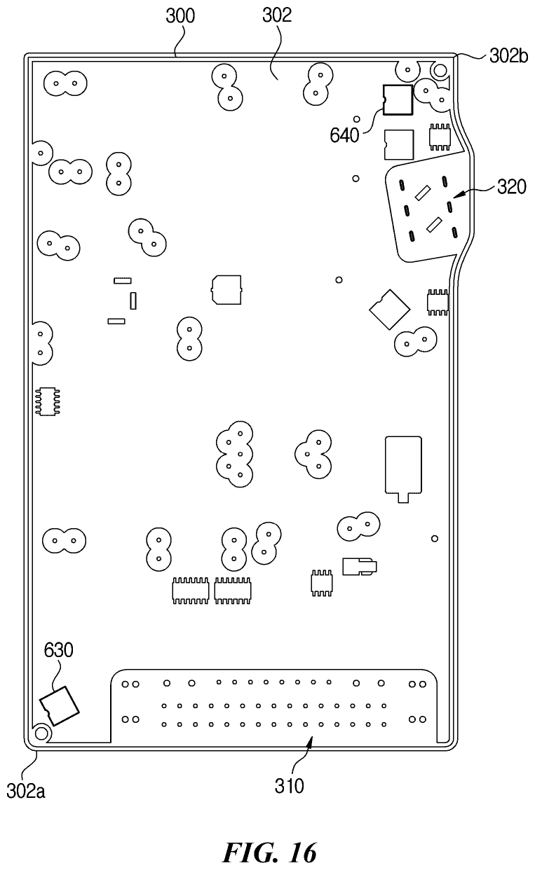

FIG. 15 shows a first surface of a first printed circuit board included in an electronic control apparatus according to an embodiment. FIG. 16 shows a second surface of a first printed circuit board included in an electronic control apparatus according to an embodiment.

As shown in FIG. 15, the first ultraviolet sensor 610 may be positioned around a first corner 301a on the first surface 301 of the first printed circuit board 300. For example, the first ultraviolet sensor 610 may be an electrical/electronic device positioned closet to the first corner 301a on the first surface 301.

The first ultraviolet sensor 610 may be positioned around the first corner 301a such that the opening 550 of the first ultraviolet sensor 610 faces the first connector 310. Accordingly, UV-C generated in the first connector 310 may be irradiated onto the photodiode 510 through the opening 550 of the first ultraviolet sensor 610.

Also, the first ultraviolet sensor 610 may be positioned around the first corner 301a such that the opening 550 of the first ultraviolet sensor 610 faces a substantially central portion of the first printed circuit board 300. Accordingly, the first ultraviolet sensor 610 may detect UV-C generated from components mounted on the first surface 301 of the first printed circuit board 300.

As shown in FIG. 15, the second ultraviolet sensor 620 may be positioned around a second corner 301b on the first surface 301 of the first printed circuit board 300. For example, the second ultraviolet sensor 620 may be an electrical/electronic device positioned closet to the second corner 301b on the first surface 301.

The second ultraviolet sensor 620 may be positioned around the second corner 301b such that the opening 550 of the second ultraviolet sensor 620 faces the second connector 320. Accordingly, UV-C generated in the second connector 320 may be irradiated onto the photodiode 510 through the opening 550 of the second ultraviolet sensor 620.

Also, the second ultraviolet sensor 620 may be positioned around the second corner 301b such that the opening 550 of the second ultraviolet sensor 620 faces the substantially central portion of the first printed circuit board 300. Accordingly, the second ultraviolet sensor 620 may detect UV-C generated from components mounted on the first surface 301 of the first printed circuit board 300.

As shown in FIG. 16, the third ultraviolet sensor 630 may be positioned around a third corner 302a on the second surface 302 of the first printed circuit board 300. For example, the third ultraviolet sensor 630 may be an electrical/electronic device positioned closet to the third corner 302a on the second surface 302.

Also, the third ultraviolet sensor 630 may be positioned around the third corner 302a such that the opening 550 of the third ultraviolet sensor 630 faces the first connector 310. Accordingly, UV-C generated in the first connector 310 may be irradiated onto the photodiode 510 through the opening 550 of the third ultraviolet sensor 630.

Also, the third ultraviolet sensor 630 may be positioned around the third corner 302a such that the opening 550 of the third ultraviolet sensor 630 faces the substantially central portion of the first printed circuit board 300. Accordingly, the third ultraviolet sensor 630 may detect UV-C generated from components mounted on the second surface 302 of the first printed circuit board 300.

As shown in FIG. 16, the fourth ultraviolet sensor 640 may be positioned around a fourth corner 302b on the second surface 302 of the first printed circuit board 300. For example, the fourth ultraviolet sensor 640 may be an electrical/electronic device positioned closet to the fourth corner 302b on the second surface 302.

The fourth ultraviolet sensor 640 may be positioned around the fourth corner 302b such that the opening 550 of the fourth ultraviolet sensor 640 faces the second connector 320. Accordingly, UV-C generated in the second connector 320 may be irradiated onto the photodiode 510 through the opening 550 of the fourth ultraviolet sensor 640.

Also, the fourth ultraviolet sensor 640 may be positioned around the fourth corner 302b such that the opening 550 of the fourth ultraviolet sensor 640 faces the substantially central portion of the first printed circuit board 300. Accordingly, the fourth ultraviolet sensor 640 may detect UV-C generated from components mounted on the second surface 302 of the first printed circuit board 300.

So far, a case in which the ultraviolet sensor 12 is positioned around the corners 301a, 301b, 302a, and 302b of the first printed circuit board 300 has been described. However, the positions of the ultraviolet sensor 12 is not limited to those shown in FIG. 15 or 16. For example, the ultraviolet sensor 12 may be provided at an edge region of the first printed circuit board 300. Accordingly, the ultraviolet sensor 12 may detect UV-C generated from components mounted on the first surface 301 or the second surface 302 of the first printed circuit board 300.

So far, an embodiment in which the ultraviolet sensor 12 is positioned on the first printed circuit board 300 on which the first connector 310 and the second connector 320 are mounted has been described.

The positions of the ultraviolet sensor 12 are not limited to these. For example, the ultraviolet sensor 12 may be positioned on a third printed circuit board that is different from the first printed circuit board 300. A sensor module including the ultraviolet sensor 12 and the third printed circuit board is referred to as an ‘ultraviolet sensor module’.

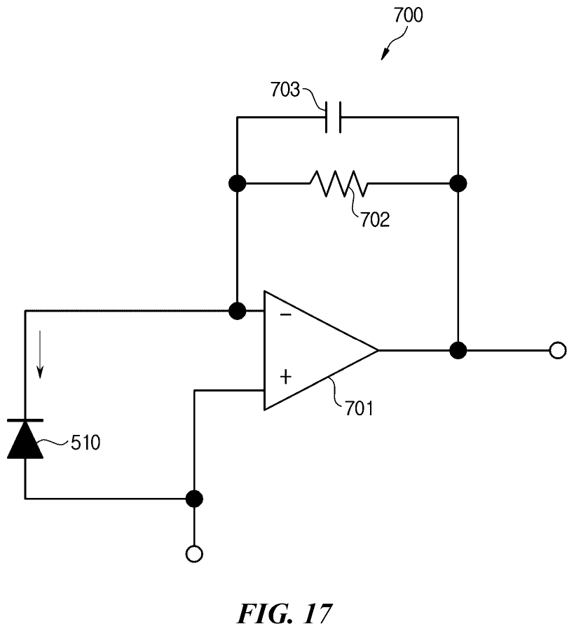

FIG. 17 shows an example of a circuit configuration of an ultraviolet sensor module included in an electronic control apparatus according to an embodiment.

As shown in FIG. 17, an ultraviolet sensor module 700 may include a photodiode 510, an amplifier 701, a capacitor 702, and/or an electrical resistor 703. The photodiode 510, the amplifier 701, the capacitor 702, and/or the electrical resistor 703, shown in FIG. 17 may be mounted on the third printed circuit board. The amplifier 701, the capacitor 702, and/or the electrical resistor 703, shown in FIG. 17 may not correspond to essential components of the ultraviolet sensor 12, and the amplifier 701, the capacitor 702, and/or the electrical resistor 703 may be omitted.

The photodiode 510 may include an anode and a cathode, and allow external current flowing from the anode to the cathode, and block external current flowing from the cathode to the anode. Also, the photodiode 510 may absorb ultraviolet light, particularly, UV-C, and generate reverse current flowing from the cathode to the anode.

The amplifier 701 may include a positive input terminal, a negative input terminal, and an output terminal, wherein the positive input terminal may be connected to the anode of the photodiode 510 and the negative input terminal may be connected to the cathode of the photodiode 510. A voltage of the output terminal of the amplifier 701 may correspond to an output signal of the ultraviolet sensor 12, that is, an ultraviolet detected signal.

The capacitor 702 and the electrical resistor 703 may be connected in parallel to each other between the negative input terminal and the output terminal of the amplifier 701. Reverse current generated in the photodiode 510 may pass through the electrical resistor 703 to thereby generate a potential difference between both ends of the electrical resistor 703, and accordingly, a potential (that is, a voltage) of the output terminal of the amplifier 701 may increase.

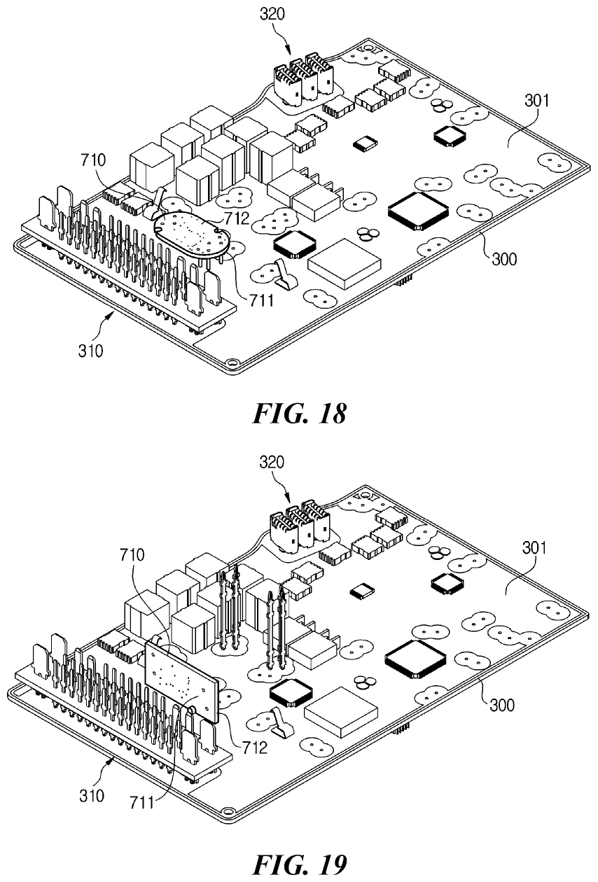

FIG. 18 shows an example of a first printed circuit board and an ultraviolet sensor module included in an electronic control apparatus according to an embodiment. FIG. 19 shows an example of a first printed circuit board and an ultraviolet sensor module included in an electronic control apparatus according to an embodiment.

The ultraviolet sensor module 700 may include a third printed circuit board 710, a photodiode 510 mounted on the third printed circuit board 710, and other circuits 701, 702, and 703.

As shown in FIG. 18, the third printed circuit board 710 of the ultraviolet sensor module 700 may be positioned on the first surface 301 of the first printed circuit board 300 in such a way as to be parallel to the first printed circuit board 300. The third printed circuit board 710 may be electrically connected to the first printed circuit board 300 through a plurality of pins.

The third printed circuit board 710 may include a third surface 711 facing the first surface 301 of the first printed circuit board 300, and a fourth surface 712 being toward an opposite direction of a direction toward the first printed circuit board 300.

The photodiode 510 for detecting UV-C may be mounted on the third surface 711 of the third printed circuit board 710. Accordingly, the photodiode 510 may face the first surface 301 of the first printed circuit board 300. In other words, the photodiode 510 may face the first connector 310 and the second connector 320 provided on the first surface 301. Accordingly, the photodiode 510 may detect UV-C generated by a spark or arc of the first connector 310 or the second connector 320.

As shown in FIG. 19, the third printed circuit board 710 of the ultraviolet sensor module 700 may be positioned on the first surface 301 of the first printed circuit board 300 in such a way as to be parallel to the first printed circuit board 300. The third printed circuit board 710 may be electrically connected to the first printed circuit board 300 through a plurality of pins.

The third printed circuit board 710 may include a third surface 711 positioned on the first surface 301 of the first printed circuit board 300 toward the first connector 310, and a fourth surface 712 positioned toward the second connector 320.

The photodiodes 510 may be mounted on the third surface 711 and the fourth surface 712 of the third printed circuit board 710. Accordingly, the photodiode 510 mounted on the third surface 711 may face the first connector 310 positioned on the first surface 301 of the first printed circuit board 300, and the photodiode 510 mounted on the fourth surface 712 may face the second connector 320 positioned on the first surface 301 of the first printed circuit board 301. Accordingly, the photodiode 510 mounted on the third surface 711 may detect UV-C generated by a spark or arc of the first connector 310 on the first surface 301 of the first printed circuit board 300, and the photodiode 510 mounted on the fourth surface 712 may detect UV-C generated by a spark or arc of the second connector 320 on the first surface 301 of the first printed circuit board 300.

As described above, the ultraviolet sensor 12 or the ultraviolet sensor module 700 included in the electronic control apparatus 10 may detect UV-C generated by a spark or arc generated in the first printed circuit board 300. The electronic control apparatus 10 may control power that is to be supplied to the electronic control apparatus 10 or provide a warning message to a driver through the display or speaker of the vehicle, in response to detection of UV-C by the ultraviolet sensor 12 or the ultraviolet sensor module 700.

Accordingly, a fire occurred by a spark and/or arc may be prevented from spreading from the electronic control apparatus 10 to other components of the vehicle.

According to an aspect of the disclosure, an electronic control apparatus and brake apparatus capable of detecting an arc or spark as a starting point of a fire that occurs in an electrical/electronic device may be provided. Accordingly, a fire which occurs in the electronic control apparatus and the brake apparatus may be prevented, suppressed, or minimized.

Meanwhile, the disclosed embodiments may be implemented in the form of a recording medium storing instructions executable by a computer. The instructions may be stored in the form of a program code, and when executed by a processor, the instructions may create a program module to perform operations of the disclosed embodiments. The recording medium may be implemented as a computer-readable recording medium.

The computer-readable recording medium may include all kinds of recording media storing instructions that can be interpreted by a computer. For example, the computer-readable recording medium may include Read Only Memory (ROM), Random Access Memory (RAM), a magnetic tape, a magnetic disc, a flash memory, an optical data storage device, etc.

The computer-readable storage medium may be provided in the form of a non-transitory storage medium, wherein the term ‘non-transitory’ simply means that the storage medium is a tangible device, and does not include a signal (e.g., an electromagnetic wave), but this term does not differentiate between where data is semi-permanently stored in the storage medium and where the data is temporarily stored in the storage medium. For example, a ‘non-transitory storage medium’ may include a buffer in which data is temporarily stored.

So far, the disclosed embodiments have been described with reference to the accompanying drawings. It will be understood by one of ordinary skill in the technical art to which the disclosure belongs that the disclosure can be embodied in different forms from the disclosed embodiments without changing the technical spirit and essential features of the present disclosure. Thus, it should be understood that the embodiments described above are merely for illustrative purposes and not for limitation purposes in all aspects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic control apparatus, comprising:
a printed circuit board on which electrical circuits are mounted;
a power connector provided on the printed circuit board and electrically connected to an external power source;
a power circuit configured to receive external power through the power connector and supply power to the electrical circuits;
an ultraviolet sensor mounted on the printed circuit board, and configured to detect ultraviolet light and output an ultraviolet detected signal corresponding to the detection of the ultraviolet light; and
a processor configured to block power supply to at least one part of the electrical circuits in response to the ultraviolet detected signal from the ultraviolet sensor.

2. The electronic control apparatus of claim 1, wherein the ultraviolet sensor includes a photodiode configured to output the ultraviolet detected signal corresponding to detection of Ultraviolet-C (UV-C) having a wavelength range of 100 nm to 280 nm.

3. The electronic control apparatus of claim 2, wherein the ultraviolet sensor includes
a sensor substrate supporting the photodiode,
a side wall surrounding the photodiode, and
an opening through which the UV-C passes.

4. The electronic control apparatus of claim 3, wherein the ultraviolet sensor is provided on the printed circuit board wherein the opening faces the power connector.

5. The electronic control apparatus of claim 2, wherein the ultraviolet sensor is provided on the printed circuit board wherein the photodiode faces the power connector.

6. The electronic control apparatus of claim 1, wherein the ultraviolet sensor is provided around the power connector.

7. The electronic control apparatus of claim 6, wherein a distance between the ultraviolet sensor and the power connector is less than half a maximum width of the printed circuit board.

8. The electronic control apparatus of claim 1, wherein the ultraviolet sensor is provided at a corner region or an edge region of the printed circuit board.

9. The electronic control apparatus of claim 1, further comprising:
an actuator connector provided on the printed circuit board and electrically connected to an actuator;
a driving circuit configured to receive power from the power circuit and control power that is to be supplied to the actuator; and
another ultraviolet sensor provided on the printed circuit board, and configured to detect ultraviolet light and output another ultraviolet detected signal corresponding to the detection of the ultraviolet light,
wherein the processor is further configured to block power supply to the driving circuit in response to the other ultraviolet detected signal from the other ultraviolet sensor.

10. The electronic control apparatus of claim 9, wherein the other ultraviolet sensor includes another photodiode configured to output the other ultraviolet detected signal corresponding to detection of Ultraviolet-C (UV-C) having a wavelength range of 100 nm to 280 nm.

11. The electronic control apparatus of claim 10, wherein the other ultraviolet sensor is provided on the printed circuit board wherein the other photodiode faces the actuator connector.

12. The electronic control apparatus of claim 9, wherein the other ultraviolet sensor is provided around the actuator connector.

13. The electronic control apparatus of claim 12, wherein a distance between the other ultraviolet sensor and the power connector is less than half a maximum width of the printed circuit board.

14. The electronic control apparatus of claim 1, wherein the processor is further configured to provide a warning message to a driver through a display or a speaker of a vehicle, in response to the ultraviolet detected signal from the ultraviolet sensor.

15. An electronic control apparatus, comprising:
a first printed circuit board on which electrical circuits are mounted;
a power connector provided on the first printed circuit board and electrically connected to an external power source;
a power circuit configured to receive external power from the power connector and supply power to the electrical circuits;
an ultraviolet sensor module including a second printed circuit board electrically connected to the first printed circuit board, and an ultraviolet sensor provided on the second printed circuit board and configured to output an ultraviolet detected signal corresponding to detection of ultraviolet light; and
a processor configured to block power supply to at least one part of the electrical circuits in response to the ultraviolet detected signal from the ultraviolet sensor module.

16. The electronic control apparatus of claim 15, wherein
the second printed circuit board is provided parallel to the first printed circuit board, and
the ultraviolet sensor is provided on a first surface of the second printed circuit board, the first surface facing the first printed circuit board.

17. The electronic control apparatus of claim 15, further comprising:
an actuator connector provided on the first printed circuit board and electrically connected to an actuator; and
a driving circuit configured to receive power from the power circuit and control power that is to be supplied to the actuator,
wherein the ultraviolet sensor module further comprises another ultraviolet sensor provided on the second printed circuit board and configured to output another ultraviolet detected signal corresponding to detection of ultraviolet light, and
the processor is further configured to block power supply to the driving circuit in response to the other ultraviolet detected signal from the other ultraviolet sensor.

18. The electronic control apparatus of claim 17, wherein
the second printed circuit board is provided vertical to the first printed circuit board,
the ultraviolet sensor is provided on a first surface of the second printed circuit board, facing the power connector, and
the other ultraviolet sensor is provided on a second surface of the second printed circuit board, the first surface facing the actuator connector.

19. The electronic control apparatus of claim 15, wherein the processor is further configured to provide a warning message to a driver through a display or a speaker of a vehicle, in response to the ultraviolet detected signal from the ultraviolet sensor.

20. A brake apparatus, comprising:
a valve;
a motor, and
an electronic control apparatus configured to drive at least one of the valve and the motor,
wherein the electronic control apparatus comprises:
a printed circuit board;
a power connector provided on the printed circuit board and electrically connected to an external power source;
a power circuit configured to receive external power through the power connector and supply power to electrical circuits;
a first ultraviolet sensor provided around the power connector, and configured to detect ultraviolet light and output a first ultraviolet detected signal corresponding to the detection of the ultraviolet light;
an actuator connector provided on the printed circuit board and electrically connected to at least one of the valve and the motor;
a driving circuit configured to receive power from the power circuit and control power that is to be supplied to at least one of the valve and the motor;
a second ultraviolet sensor provided around the actuator connector, and configured to detect ultraviolet light and output a second ultraviolet detected signal corresponding to the detection of the ultraviolet light; and
a processor configured to limit an operation of at least one of the electrical circuits and the driving circuit, in response to the first ultraviolet detected signal and the second ultraviolet detected signal.
